(19) United States
(12) Patent Application Publication
(10) Pub. No.: US 2003/0168662 A1
(43) Pub. Date: Sep. 11, 2003

(54) Integrated circuit with improved clock distribution

(76) Inventor: Pramod Pandey, Singapore (SG)

Correspondence Address: Siemens Corporation, Intellectual Property Department, 186 Wood Avenue South, Iselin, NJ, 08830, US

(21) Appl. No.: 10/094,069

(22) Filed: Mar. 8, 2002

(51) Int. Cl. H03B 1/00

(52) U.S. Cl. 257/74; 331/74

(57) ABSTRACT

An IC with improved reference clock distribution is provided, comprising a reference oscillator (2) and several subcircuits (4 to 7), each connected via a clock input terminal (41, 51, 61, 71) and a clock tree (8) with the oscillator (2). Via that clock tree (8), a harmonic clock signal is distributed, which is shaped into a square wave within the subcircuits. The IC described features significantly less signal distortions and requires no introduction of additional delay elements at the top level clock tree (8).

### FIELD OF THE INVENTION

The present invention relates generally to integrated circuits and, more particularly, to clock distribution in integrated circuits.

### BACKGROUND OF THE INVENTION

Integrated circuits (ICs) such as those used in communication devices usually comprise several functional blocks or modules. A reference clock signal is used to, for example, exchange data over a data bus in a synchronized manner. To generate the reference clock signal, a reference oscillator such as a crystal oscillator is used. The oscillator is located on the IC and is coupled to the clock input terminals of different modules or functional blocks, forming a clock tree. Due to the variations in the lengths of the different clock signal paths and loads, the clock signal at the different modules will have different delays (referred to as “clock skew”). This can impact the performance or functionality of the IC, particularly for high speed applications.

Conventionally, a layout tool at the stage of circuit design are used to perform a clock tree synthesis to reduce clock skew at the different modules. The layout tool introduces several delay elements (e.g., chains of buffers or amplifiers), at different places of the clock tree to match the delay of the clock signals at the different modules. However, the introduction of delay elements undesirably increases the size of the IC.

As described in the foregoing, it is desirable to reduce or eliminate clock skew without the need for additional delay elements.

### SUMMARY OF THE INVENTION

It is an object of the present invention to provide an integrated circuit with improved reference clock distribution. According to the present invention, integrated circuit comprises a reference clock signal generator having an output terminal. The reference clock signal generator generates a sinusoidal clock signal at the output terminal. The output terminal of the clock signal generator is coupled to a reference clock input terminal of a first subcircuit. The first subcircuit includes a signal converter coupled to said input terminal for converting the sinusoidal clock signal into a square wave signal. The integrated circuit further comprises a second subcircuit having a reference clock input terminal coupled to the output terminal of the clock signal generator and having a signal converter coupled to the input terminal to convert the sinusoidal clock signal into a square wave signal.

The distribution of a sinusoidal (i.e., a harmonic clock signal) via a clock tree results in significantly less signal distortion than with the use of a square wave. This is because high frequency effects involved with high-speed square-wave clock signal transmission are avoided. In one embodiment, high frequency signals are restricted to the subcircuit level. The transmission of a sinusoidal reference clock signal from the reference clock generator to the input terminals of functional blocks of the chip avoids variations of the signal phase due to parasitics. Additionally, due to the missing higher harmonics of the signal, signal distortions on the IC are reduced significantly.

Within the clock tree, no clock tree synthesis or introduction of buffers or other delay elements is required. Therefore, the IC design is simplified significantly and chip area is also reduced. In one embodiment, a subcircuit comprises a signal converter for conversion of the sinusoidal clock signal into a square wave signal. Since all the square waves at the different subcircuits of the IC are derived from the same reference generator, they have the same phase. Therefore, clock skew is eliminated or reduced.

In a preferred embodiment of the present invention, the first and second subcircuits comprise an AC (alternating current)-coupler connected between said reference clock input terminal and said signal converter. The AC-coupler avoids DC-offsets at the input terminals of the signal converters. Advantageously, all signal converters of the subcircuits of the IC share the same threshold levels for conversion of the sinusoidal signal into the square wave signal. As a result, the square wave signals of the different subcircuits have the same duty cycle as well as a further improved accuracy of the relative signal phase in comparison to the other square wave signals at output terminals of the signal converters.

According to another preferred embodiment of the present invention, an analog amplifier is provided having an input terminal and an output terminal. The input terminal of the amplifier is connected to the output terminal of the signal generator and the output terminal being connected to the reference clock input terminal of subcircuits.

Parasitic resistances within the clock signal tree between the reference clock generator and the input terminals for clock signals at the different subcircuits, modules, or functional blocks on the IC may cause, especially with long electric lines, signal attenuations, which results in an attenuation of the amplitude of the clock signal. To compensate for amplitude attenuation in the clock signal, the analog amplifier, which is preferably connected directly at the sinusoidal output terminal of the crystal oscillator, amplifies the harmonic signal for distributed to the input terminals of the functional blocks.

According to a further, improved embodiment of the present invention, the reference clock signal generator is a crystal oscillator. A crystal oscillator usually comprises a quartz oscillating device, which in the present arrangement may be connected externally to a chip comprising the circuit arrangement described. A crystal oscillator provides for a reference clock signal with very high accuracy and stability. In a further, preferred embodiment of the present invention, the first subcircuit comprises a frequency synthesizer circuit having an input terminal and an output terminal, said input terminal being connected to said signal converter and providing a derived clock signal.

In one embodiment, the frequency synthesizer preferably is a phase-locked-loop circuit (PLL), providing a derived clock signal with a signal frequency different from the frequency of the reference clock signal. Of course, when different clock frequencies within one module or functional block are necessary, several PLLs can be provided which, with their input terminals, are coupled to the signal converter.

The subcircuits of the IC, for example, micro-controllers, micro-processors, network processing blocks, digital signal processing blocks, digital filters, or the like. These modules or subcircuits may comprise several, for example, flip flops, synchronous memories, I/O-interfaces to exchange data over a data bus link, or other types of components. In one embodiment, the IC may be a network switch, a cable modem, a voice-over-IP processing unit, or other types of ICs.

The transmission line of the reference clock signal coupling the output terminal of the reference clock signal generator with the input terminals of the subcircuits may be a symmetric line to distribute the sinusoidal reference clock signal as a differential signal for improved signal immunity against distortions.

### BRIEF DESCRIPTION OF THE DRAWINGS

FIG. 1 shows a simplified block diagram of an IC in accordance with one embodiment of the invention.

### PREFERRED EMBODIMENTS OF THE INVENTION

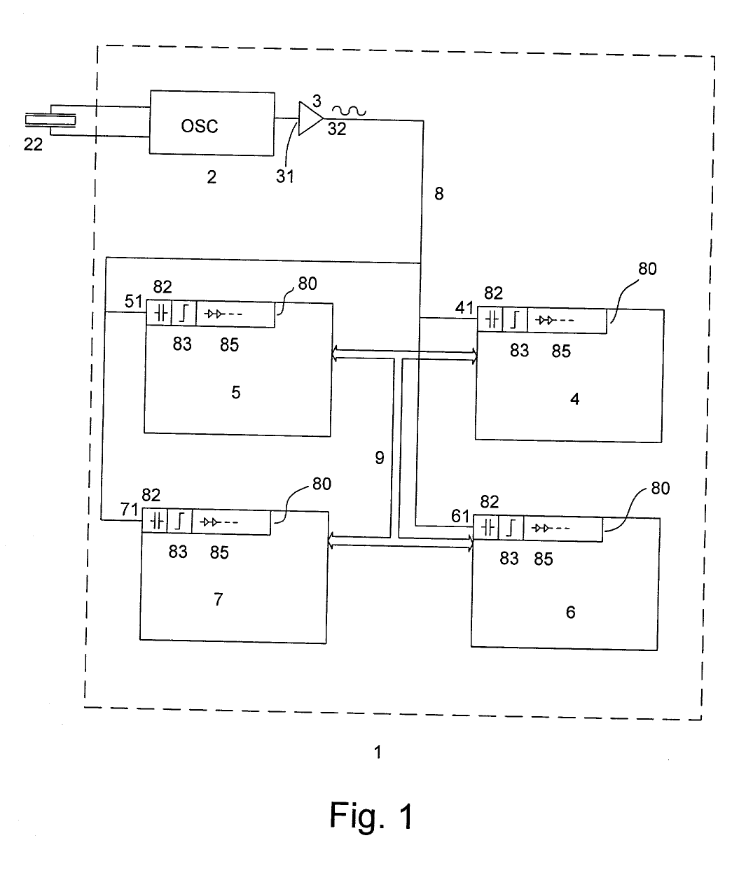

FIG. 1 shows an IC with improved clock distribution in accordance with one embodiment of the invention. As shown, the IC comprises a reference clock signal generator 2. In accordance with the invention, the reference clock signal generator generates a sine wave signal at an output terminal 21. To ensure a highly stable and accurate oscillating frequency, the oscillator includes a quartz oscillator 22. The quartz oscillator, for example, is external to the clock signal generator. Coupled to the output terminal of the clock generator is an analog amplifier. The amplifier amplifies the clock signal from the reference clock signal generator.

The IC further comprises a plurality of subcircuits, functional blocks, or modules 4, 5, 6, 7. A subcircuit comprises a clock input terminal (41, 51, 61, or 71). The input terminals of the subcircuits are coupled to the output terminal 32 of the analog amplifier via a clock tree 8. The subcircuits further comprise I/O-interfaces (not shown), which are coupled with each other via a data bus link 9.

In one embodiment, a comparator 83 is coupled to the input terminal of a subcircuit via an AC-coupler 82. The AC-coupler decouples the clock signal from any DC-offsets to ensure that all comparators of the different subcircuits switch at the same threshold. The comparator, for example, is a Schmitt-trigger which converts the harmonic clock signal into a square wave. To provide a clock frequency different from the reference clock frequency, a phase-locked-loop (PLL) is provided in the interface. The PLL is coupled to, for example, the comparator. A subcircuit may further comprise delay elements 85, such as buffers or amplifiers, for clock signal distribution within the subcircuit.

By providing a sine wave signal from the reference clock generator, clock skew is reduced or eliminated. As such, there is no relative phase delay between the clock signals of the different subcircuits, thus eliminating the need for buffers or other delay elements. Although amplitude attenuation can result from parasitic elements (e.g., resistors, inductances and capacitances), the amplitude attenuation can be compensated by the amplifier.

The subcircuits may comprise filters, digital signal processors, DSP, network processing blocks, micro-processors, micro-controllers, flip flops, synchronised memories, or I/O-interfaces. Other types of subcircuits which require highly accurate synchronous clock signals are also useful. The IC, for example, is a cable modem, a network switch, a voice-over IP processing unit, or other types of ICs, such as those requiring high clock frequencies without any clock skew.

While the invention has been particularly shown and described with reference to various embodiments, it will be recognized by those skilled in the art that modifications and changes may be made to the present invention without departing from its scope. The scope of the invention should therefore be determined not with reference to the above description but with reference to the appended claims along with their full scope of equivalents.

What is claimed is:

1. An IC with improved reference clock distribution, comprising:
a reference clock signal generator, having an output terminal and providing a sinusoidal clock signal at said output terminal;
a first subcircuit for digital signal processing having a reference clock input terminal coupled to said output terminal of said clock signal generator and having a signal converter coupled to said input terminal and converting said sinusoidal clock signal into a square wave signal; and
a second subcircuit for digital signal processing having a reference clock input terminal coupled to said output terminal of said clock signal generator and having a signal converter coupled to said input terminal and converting said sinusoidal clock signal into a square wave signal.
